(19) United States
(12) Patent Application Publication
(10) Pub. No.: US 2014/0184035 A1
(43) Pub. Date: Jul. 3, 2014

(54) Television Housing and Method of Fabricating the Same

(71) Applicant: Cheil Industries Inc., Gumi-si (KR)

(72) Inventors: Jo Won LEE, Uiwang-si (KR); Kyuong Sik CHIN, Uiwang-si (KR); Ji Yea KIM, Uiwang-si (KR); Sang Ki PARK, Uiwang-si (KR); Seung Shik SHIN, Uiwang-si (KR)

(73) Assignee: Cheil Industries Inc., Gumi-si (KR)

(21) Appl. No.: 14/132,325

(22) Filed: Dec. 18, 2013

(30) Foreign Application Priority Data
Dec. 28, 2012 (KR) 10-2012-0157669

(51) Int. Cl. A47B 81/06; B29C 45/00; H05K 5/00; B29C 45/73

(52) U.S. Cl. CPC A47B 81/06; B29C 45/7337; B29C 45/0025; H05K 5/0017
USPC 312/7.2; 156/242

(57) ABSTRACT

Disclosed herein is a television housing and a method of fabricating the same. The television housing includes a stainless steel (SUS) frame and a plastic member adjoining at least one surface of the stainless steel frame. The plastic member includes: a base resin including about 60 wt % to about 95 wt % of (A) a polycarbonate resin and about 5 wt % to about 40 wt % of (B) a rubber-modified aromatic vinyl graft copolymer resin; and about 5 parts by weight to about 25 parts by weight of (C) bondable glass fibers based on about about 100 parts by weight of the base resin including the (A) polycarbonate resin and the (B) rubber-modified aromatic vinyl graft copolymer resin, and has a tensile strength from about 70 MPa to about 130 MPa at about 23° C. The plastic member employs the bondable glass fibers, and thus can prevent whitening due to an ejector pin upon release at high temperature.

### CROSS-REFERENCE TO RELATED APPLICATION

This application claims priority under 35 USC Section 119 to and the benefit of Korean Patent Application No. 10-2012-0157669, filed Dec. 28, 2012, the entire disclosure of which is incorporated herein by reference.

### FIELD OF THE INVENTION

The present invention relates to a television housing and a method of fabricating the same. More particularly, the present invention relates to a television housing, which employs bondable glass fibers and thus can prevent whitening due to an ejector pin upon release at high temperatures, and to a method of fabricating the same.

### BACKGROUND OF THE INVENTION

A blend (PC/ABS) of polycarbonate (PC) and ABS resins can be used for exterior materials of electronic products requiring high gloss, high flowability, high impact resistance, and the like. However, a blend including only PC/ABS exhibits poor stiffness and dimensional stability. Thus, a reinforced material in which PC/ABS is reinforced with glass fiber has been developed.

Glass fiber-reinforced PC/ABS resin is used in products requiring dimensional stability and high stiffness, and is also widely used for internal components of electric/electronic products due to the excellent flame retardancy thereof. However, such a glass fiber-reinforced resin exhibits low quality external appearance. Thus, it is difficult to use the glass fiber-reinforced resin in an exterior component of electric/electronic products, such as a television housing, and the like. For example, when a television housing formed of such a glass fiber-reinforced PC/ABS resin is released during molding at a temperature of about 30° C. or more, there is a possibility of whitening due to an ejector pin. Such a problem acts as a limit in extending applications of the glass fiber-reinforced PC/ABS.

Therefore, there is a need for a television housing using glass fiber-reinforced PC/ABS, which exhibits excellent external appearance and can prevent whitening upon release at high temperatures while maintaining excellent flame retardancy, dimensional stability, and stiffness.

### SUMMARY OF THE INVENTION

The present invention provides a television housing, which can exhibit excellent properties in terms of flame retardancy, dimensional stability, stiffness and/or external appearance, and can prevent whitening due to an ejector pin upon release at high temperature, and a method of fabricating the same.

The television housing includes: a stainless steel (SUS) frame; and a plastic member adjoining at least one surface of the stainless steel frame, wherein the plastic member includes: a base resin including about 60% by weight (wt %) to about 95 wt % of (A) a polycarbonate resin; and about 5 wt % to about 40 wt % of (B) a rubber-modified aromatic vinyl graft copolymer resin; wherein the plastic member further includes about 5 parts by weight to about 25 parts by weight of (C) bondable glass fibers, based on about 100 parts by weight of the base resin of the (A) polycarbonate resin and the (B) rubber-modified aromatic vinyl graft copolymer resin, and has a tensile strength from about 70 MPa to about 130 MPa at about 23° C.

In one embodiment, the plastic member may be molded by a steam molding process.

In one embodiment, the steam molding process may be rapid heat cycle molding (RHCM).

In one embodiment, the bondable glass fibers may be coated with a resin including at least one of epoxy, urethane, and silane resins.

In one embodiment, the plastic member may further include at least one of a phosphorus flame retardant and a halogen flame retardant.

In one embodiment, the plastic member may further include at least one of impact reinforcing agents, anti-dripping agents, antimicrobials, heat stabilizers, antioxidants, release agents, light stabilizers, inorganic additives, surfactants, plasticizers, lubricants, antistatic agents, and colorants.

The present invention also relates to a method of fabricating a television housing. The method includes: preparing a plastic member by injection of (A) a polycarbonate resin, (B) a rubber-modified aromatic vinyl graft copolymer resin and (C) bondable glass fibers into a mold in a steam molding process, followed by releasing the plastic member at about 30° C. to about 90° C.; and coupling the plastic member to a stainless steel (SUS) frame.

In one embodiment, the plastic member may have a tensile strength from about 70 MPa to about 130 MPa at about 23° C.

In one embodiment, the steam molding process may be rapid heat cycle molding (RHCM).

### BRIEF DESCRIPTION OF THE DRAWINGS

The above and other aspects, features and advantages of the invention will become apparent from the following description of embodiments given in conjunction with the accompanying drawing, in which:

FIG. 1 is a sectional view of a television housing according to one embodiment of the present invention.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

The present invention will become apparent with reference to the accompanying drawings. In the drawings, the sizes of components may be exaggerated for clarity, without being limited thereto.

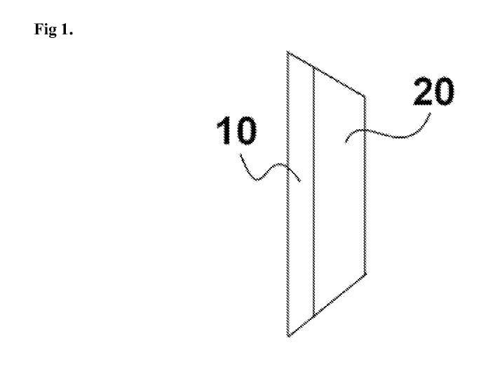

FIG. 1 is a sectional view of a television housing according to one embodiment of the present invention. Referring to FIG. 1, the television housing according to one embodiment of the invention includes: a stainless steel (SUS) frame 10; and a plastic member 20 adjoining at least one surface of the stainless steel frame 10.

The stainless steel frame 10 and the plastic member 20 may have various shapes, without being limited to the shapes in the drawing. However, at least one surface of the stainless steel frame 10 adjoins at least one surface of the plastic member 20. The adjoining structure may be realized by bonding, insertion or the like, without being limited thereto.

The stainless steel frame 10 may be a typical product which is used in a television housing and is commercially available.

The plastic member 20 includes: a base resin including (A) a polycarbonate resin; and (B) a rubber-modified aromatic vinyl graft copolymer resin; and the plastic member further includes (C) bondable glass fibers. The plastic member has a tensile strength from about 70 MPa to about 130 MPa at about 23° C.

(A) Polycarbonate Resin

The polycarbonate resin may be any typical polycarbonate resin without limitation. For example, the polycarbonate resin may be a polycarbonate resin prepared by reacting one or more diphenols represented by Formula 1 with phosgene, halogen acid ester, and/or carbonic acid ester. In addition, at least two diphenols represented by Formula 1 may be combined to form a repeat unit of the polycarbonate resin.

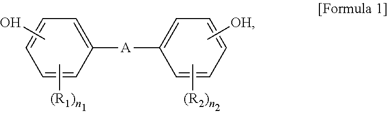

wherein A is a single bond, substituted or unsubstituted C₁ to C₃₀ linear or branched alkylene, substituted or unsubstituted C₂ to C₅ alkenylene, substituted or unsubstituted C₂ to C₅ alkylidene, substituted or unsubstituted C₁ to C₃₀ linear or branched haloalkylene, substituted or unsubstituted C₅ to C₆ cycloalkylene, substituted or unsubstituted C₅ to C₆ cycloalkenylene, substituted or unsubstituted C₅ to C₁₀ cycloalkylidene, substituted or unsubstituted C₆ to C₃₀ arylene, substituted or unsubstituted C₁ to C₂₀ linear or branched alkoxylene, a halogen acid ester group, a carbonic acid ester group, CO, S, or SO₂; R₁ and R₂ are the same or different and are each independently substituted or unsubstituted C₁ to C₃₀ alkyl or substituted or unsubstituted C₆ to C₃₀ aryl; and n₁ and n₂ are the same or different and are each independently an integer from 0 to 4.

As used herein, the term “substituted” means that a hydrogen atom is substituted with a substituent, such as a halogen atom, a hydroxyl group, a nitro group, a cyano group, an amino group, an azido group, an amidino group, a hydrazino group, a carbonyl group, a carbamyl group, a thiol group, an ester group, a carboxyl group or a salt thereof, a sulfonic acid group or a salt thereof, a phosphate group or a salt thereof, a C₁ to C₂₀ alkyl group, a C₂ to C₂₀ alkenyl group, a C₂ to C₂₀ alkynyl group, a C₁ to C₂₀ alkoxy group, a C₆ to C₃₀ aryl group, a C₆ to C₃₀ aryloxy group, a C₃ to C₃₀ cycloalkyl group, a C₃ to C₃₀ cycloalkenyl group, a C₃ to C₃₀ cycloalkynyl group, or a combination thereof.

Examples of diphenols may include without limitation hydroquinone, resorcinol, 4,4′-biphenol, 2,2-bis(4-hydroxyphenyl)propane (also referred to as ‘bisphenol-A’), 2,4-bis(4-hydroxyphenyl)-2-methylbutane, bis(4-hydroxyphenyl)methane, 1,1-bis(4-hydroxyphenyl)cyclohexane, 2,2-bis(3-chloro-4-hydroxyphenyl)propane, 2,2-bis(3,5-dimethyl-4-hydroxyphenyl)propane, 2,2-bis(3,5-dichloro-4-hydroxyphenyl)propane, 2,2-bis(3,5-dibromo-4-hydroxyphenyl)propane, bis(4-hydroxyphenyl)sulfoxide, bis(4-hydroxyphenyl)ketone, bis(4-hydroxyphenyl)ether, and the like, and combinations thereof. For example, the diphenol may include 2,2-bis(4-hydroxyphenyl)propane, 2,2-bis(3,5-dichloro-4-hydroxyphenyl)propane, and/or 1,1-bis(4-hydroxyphenyl)cyclohexane, for example 2,2-bis(4-hydroxyphenyl)propane.

The polycarbonate resin may have a weight average molecular weight (Mw) from about 10,000 g/mol to about 200,000 g/mol, for example, from about 15,000 g/mol to about 80,000 g/mol, without being limited thereto.

Examples of the polycarbonate resin may include without limitation homopolymers, copolymers, for example prepared from at least two diphenols, and mixtures thereof. Other examples of the polycarbonate resin may include without limitation linear polycarbonate resins, branched polycarbonate resins and/or polyestercarbonate copolymer resins.

For example, the linear polycarbonate resin may be a bisphenol-A polycarbonate resin, or the like. For example, the branched polycarbonate resin may be prepared by reacting a polyfunctional aromatic compound, such as trimellitic anhydride, trimellitic acid, and the like with diphenols and carbonate. Here, the polyfunctional aromatic compound may be present in an amount of about 0.05 mol % to about 2 mol % based on the total amount of the branched polycarbonate resin. In addition, for example, the polyestercarbonate copolymer resin may be prepared by reacting a bifunctional carboxylic acid with one or more diphenols and carbonates. Here, the carbonates may include diaryl carbonate such as diphenyl carbonate and the like, ethylene carbonate, and the like.

In one embodiment, the polycarbonate resin may have a melt index (MI) from about 5 g/10 min to about 120 g/10 min, as measured at about 300° C. under a load of about 1.2 kg in accordance with ISO 1133. The polycarbonate resin may be prepared by combination of at least two polycarbonates having different melt indexes. For example, the polycarbonate resin may be prepared by mixing about 20 wt % to about 60 wt % of a polycarbonate resin having a melt index from about 5 g/10 min to about 15 g/10 min, about 20 wt % to about 60 wt % of a polycarbonate resin having a melt index from about 16 g/10 min to about 50 g/10 min, and about 40 wt % of a polycarbonate resin having a melt index from about 51 g/10 min to about 120 g/10 min. In this case, the plastic member can have an excellent balance of properties.

The base resin may include the polycarbonate resin in an amount of about 60 wt % to about 95 wt %, for example, about 70 wt % to about 90 wt %, based on the total weight (100 wt %) of the base resin including the polycarbonate resin (A) and the rubber-modified aromatic vinyl graft copolymer resin (B) in the plastic member. In some embodiments, the base resin may include the polycarbonate resin in an amount of about 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, or 95 wt %. Further, according to some embodiments of the present invention, the amount of the polycarbonate resin can be in a range from about any of the foregoing amounts to about any other of the foregoing amounts.

When the base resin includes the polycarbonate resin in an amount within this range, the plastic member can have an excellent balance of impact strength, heat resistance, and processability.

(B) Rubber-Modified Aromatic Vinyl Graft Copolymer Resin

The rubber-modified aromatic vinyl graft copolymer resin is a polymer, in which particles of a rubbery polymer are dispersed in a matrix (continuous phase) including an aromatic vinyl polymer and the like. For example, the rubber-modified aromatic vinyl graft copolymer resin may be polymerized by adding an aromatic vinyl monomer, and optionally, a monomer copolymerizable with the aromatic vinyl monomer, to the rubbery polymer. Examples of the rubber-modified aromatic vinyl graft copolymer resin may include without limitation acrylonitrile-butadiene-styrene copolymer resins (ABS resins), acrylonitrile-ethylene propylene rubber-styrene copolymer resins (AES resins), acrylonitrile-acrylic rubber-styrene copolymer resins (AAS resins), and the like, and combinations thereof, without being limited thereto.

Generally, the rubber-modified aromatic vinyl graft copolymer resin may be prepared by any polymerization method known in the art, such as emulsion polymerization, suspension polymerization, bulk polymerization, and the like. In addition, the rubber-modified aromatic vinyl graft copolymer resin may be typically prepared by extrusion of a mixture of a graft copolymer resin and a copolymer resin.

Regardless of the method used to prepare the rubber-modified aromatic vinyl graft copolymer resin, including a single process without separate preparation of the graft copolymer resin and the copolymer resin in bulk polymerization, the rubber particles (rubbery polymer) may be present in an amount of about 5 wt % to about 50 wt % in the final rubber-modified aromatic vinyl graft copolymer resin. In some embodiments, the final rubber-modified aromatic vinyl graft copolymer resin can include the rubber particles in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 wt %. Further, according to some embodiments of the present invention, the amount of the rubber particles can be in a range from about any of the foregoing amounts to about any other of the foregoing amounts.

In addition, the rubber particles may have a Z-average particle size from about 0.05 μm to about 6.0 μm, without being limited thereto. Within this range, the plastic member can exhibit excellent properties, such as impact resistance, and the like.

In one embodiment, the rubber-modified aromatic vinyl graft copolymer resin (B) may include only (B1) a graft copolymer resin, or may be prepared using both (B1) a graft copolymer resin and (B2) a copolymer resin. When both (B1) and (B2) are used, the amounts of (B 1) and (B2) can depend on compatibility, as will be appreciated by the skilled artisan.

(B1) Graft Copolymer Resin

The graft copolymer resin may be obtained by graft copolymerization of an aromatic vinyl monomer and a monomer copolymerizable with the aromatic vinyl monomer with a rubbery polymer. In addition, the graft copolymer resin may further include a monomer imparting processability and heat resistance, as needed.

Examples of the rubbery polymer may include without limitation diene rubbers such as polybutadiene, isoprene, poly(styrene-butadiene), poly(acrylonitrile-butadiene) and the like; saturated rubbers obtained by adding hydrogen to the diene rubbers; acrylic rubbers such as, polybutyl acrylic acid, and the like; ethylene-propylene-diene monomer terpolymers (EPDM); and the like, and combinations thereof. In exemplary embodiments, the rubbery polymer includes diene rubber, for example butadiene rubber.

The graft copolymer resin may include the rubbery polymer in an amount of about 5 wt % to about 65 wt %, for example, about 10 wt % to about 60 wt %, and as another example about 20 wt % to about 50 wt %, based on the total weight (100 wt %) of the graft copolymer resin. In some embodiments, the graft copolymer resin may include the rubbery polymer in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, or 65 wt %. Further, according to some embodiments of the present invention, the amount of the rubbery polymer can be in a range from about any of the foregoing amounts to about any other of the foregoing amounts.

When the graft copolymer resin includes the rubbery polymer in an amount within this range, the plastic member can have an excellent balance of impact strength and mechanical properties.

The rubbery polymer (rubber particles) may have an average particle size (Z-average) from about 0.1 μm to about 6 μm, for example, from about 0.15 μm to about 4 μm, and as another example from about 0.25 μm to about 3.5 μm. Within this range, the plastic member can exhibit excellent impact strength and external appearance.

The aromatic vinyl monomer is graft-copolymerizable with the rubbery polymer.

Examples of the aromatic vinyl monomer may include without limitation styrene, α-methylstyrene, β-methylstyrene, p-methylstyrene, para-t-butylstyrene, ethylstyrene, vinylxylene, monochlorostyrene, dichlorostyrene, dibromostyrene, vinylnaphthalene, and the like, and combinations thereof. In exemplary embodiments, the aromatic vinyl monomer can include styrene.

The graft copolymer resin may include the aromatic vinyl monomer in an amount of about 34 wt % to about 94 wt %, for example, about 36 wt % to about 80 wt %, and as another example about 40 wt % to about 60 wt %, based on the total weight (100 wt %) of the graft copolymer resin. In some embodiments, the graft copolymer resin may include the aromatic vinyl monomer in an amount of about 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, or 94 wt %. Further, according to some embodiments of the present invention, the amount of the aromatic vinyl monomer can be in a range from about any of the foregoing amounts to about any other of the foregoing amounts.

When the graft copolymer resin includes the aromatic vinyl monomer in an amount within this range, the plastic member can have an excellent balance of impact strength and mechanical properties.

Examples of the monomer copolymerizable with the aromatic vinyl monomer may include without limitation vinyl cyanide compounds such as acrylonitrile and the like, unsaturated nitrile compounds such as ethacrylonitrile, methacrylonitrile, and the like. These may be used alone or in combination thereof.

The graft copolymer resin may include the monomer copolymerizable with the aromatic vinyl monomer in an amount of about 1 wt % to about 30 wt %, for example, about 4 wt % to about 29 wt %, and as another example about 10 wt % to about 28 wt %, based on the total weight (100wt %) of the graft copolymer resin. In some embodiments, the graft copolymer resin may include the monomer copolymerizable with the aromatic vinyl monomer in an amount of about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 wt %. Further, according to some embodiments of the present invention, the amount of the monomer copolymerizable with the aromatic vinyl monomer can be in a range from about any of the foregoing amounts to about any other of the foregoing amounts.

When the graft copolymer resin includes the monomer copolymerizable with the aromatic vinyl monomer in an amount within this range, the plastic member can have an excellent balance of impact strength and mechanical properties.

Examples of the monomer imparting processability and heat resistance may include without limitation acrylic acid, methacrylic acid, maleic anhydride, N-substituted maleimide, and the like, and combinations thereof.

The graft copolymer resin may optionally include the monomer imparting processability and heat resistance in an amount of about 15 wt % or less, for example, about 0.1 wt % to about 10 wt %, based on the total weight (100wt %) of the graft copolymer resin. In some embodiments, the graft copolymer resin may optionally include the monomer imparting processability and heat resistance in an amount of about 0.1, 0.2, 0.3, 0.4, 0.5, 0.6, 0.7, 0.8, 0.9, 1, 2, 3, 4, 5, 6, 7, 8, 9, 10, 11, 12, 13, 14, or 15 wt %. Further, according to some embodiments of the present invention, the amount of the monomer imparting processability and heat resistance can be in a range from about any of the foregoing amounts to about any other of the foregoing amounts.

When the graft copolymer resin includes the monomer imparting processability and heat resistance in an amount within this range, the monomer can impart processability and heat resistance to the plastic member with no or minimal deterioration of other properties.

(B2) Copolymer Resin

The copolymer resin may be prepared using a monomer mixture excluding the rubber (rubbery polymer) from the graft copolymer resin, and a ratio of the monomers may vary with compatibility and the like. For example, the copolymer resin may be obtained by copolymerization of the aromatic vinyl monomer and the monomer copolymerizable with the aromatic vinyl monomer.

Examples of the aromatic vinyl monomer may include without limitation styrene, α-methylstyrene, β-methylstyrene, p-methylstyrene, para-t-butylstyrene, ethylstyrene, vinylxylene, monochlorostyrene, dichlorostyrene, dibromostyrene, vinylnaphthalene, and the like, and combinations thereof. In exemplary embodiments, the aromatic vinyl monomer can include styrene.

Examples of the monomer copolymerizable with the aromatic vinyl monomer may include without limitation vinyl cyanide compounds such as acrylonitrile and the like, unsaturated nitrile compounds, such as ethacrylonitrile, methacrylonitrile, and the like. These may be used alone or in combination thereof.

In another embodiment, the copolymer resin may further include the monomer imparting processability and heat resistance, as needed. Examples of the monomer imparting processability and heat resistance may include without limitation acrylic acid, methacrylic acid, maleic anhydride, N-substituted maleimide, and the like, and combinations thereof.

The copolymer resin may include the aromatic vinyl monomer in an amount of about 60 wt % to about 90 wt %, for example, about 70 wt % to about 80 wt %, based on the total weight (100 wt %) of the copolymer resin. In some embodiments, the copolymer resin may include the aromatic vinyl monomer in an amount of about 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of the aromatic vinyl monomer can be in a range from about any of the foregoing amounts to about any other of the foregoing amounts.

When the copolymer resin includes the aromatic vinyl monomer in an amount within this range, the plastic member can have an excellent balance of impact strength and mechanical properties.

The copolymer resin may include the monomer copolymerizable with the aromatic vinyl monomer in an amount of about 10 wt % to about 40 wt %, for example, about 20 wt % to about 30 wt %, based on the total weight (100 wt %) of the copolymer resin. In some embodiments, the copolymer resin may include the monomer copolymerizable with the aromatic vinyl monomer in an amount of about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40 wt %. Further, according to some embodiments of the present invention, the amount of the monomer copolymerizable with the aromatic vinyl monomer can be in a range from about any of the foregoing amounts to about any other of the foregoing amounts.

When the copolymer resin includes the monomer copolymerizable with the aromatic vinyl monomer in an amount within this range, the plastic member can have an excellent balance of impact strength and mechanical properties.

In addition, the copolymer resin may optionally include the monomer imparting processability and heat resistance in an amount of about 30 wt % or less, for example, about 0.1 wt % to about 20 wt %, based on the total weight of the copolymer resin. In some embodiments, the copolymer resin may optionally include the monomer imparting processability and heat resistance in an amount of about 0.1, 0.2, 0.3, 0.4, 0.5, 0.6, 0.7, 0.8, 0.9, 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 wt %. Further, according to some embodiments of the present invention, the amount of the monomer imparting processability and heat resistance can be in a range from about any of the foregoing amounts to about any other of the foregoing amounts.

When the copolymer resin includes the monomer imparting processability and heat resistance in an amount within this range, the monomer can impart processability and heat resistance to the plastic member with no or minimal deterioration of other properties.

In the rubber-modified aromatic vinyl graft copolymer resin (B), the graft copolymer resin (B1) may be present in an amount of about 10 wt % to about 100 wt %, for example, about 15 wt % to about 90 wt %, and the amount of the copolymer resin (B2) may be about 0 wt % to about 100 wt %, for example, about 10 wt % to about 85 wt %.

In some embodiments, the rubber-modified aromatic vinyl graft copolymer resin (B) may include the graft copolymer resin (B1) in an amount of about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100 wt %. Further, according to some embodiments of the present invention, the amount of the graft copolymer resin (B1) can be in a range from about any of the foregoing amounts to about any other of the foregoing amounts.

In some embodiments, the rubber-modified aromatic vinyl graft copolymer resin (B) may include the copolymer resin (B2) in an amount of about 0 wt % (the copolymer resin (B2) is not present), about 0 wt % (the copolymer resin (B2) is present), 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or 100 wt %. Further, according to some embodiments of the present invention, the amount of the copolymer resin (B2) can be in a range from about any of the foregoing amounts to about any other of the foregoing amounts.

When the rubber-modified aromatic vinyl graft copolymer resin (B) includes the graft copolymer resin (B1) and/or the copolymer resin (B2) in an amount within the above ranges, the plastic member can have an excellent balance of impact strength and mechanical properties.

In one embodiment, in the rubber-modified aromatic vinyl graft copolymer resin, the graft copolymer resin may be present in an amount of about 55 wt % to about 90 wt %, for example, about 60 wt % to about 80 wt %, and the copolymer resin may be present in an amount of about 10 wt % to about 45 wt %, for example, about 20 wt % to about 40 wt %. Within this range, particularly, the plastic member can exhibit excellent impact resistance.

In another embodiment, in the rubber-modified aromatic vinyl graft copolymer resin, the graft copolymer resin may be present in an amount of about 15 wt % to about 50 wt %, for example, about 20 wt % to about 40 wt %, and the copolymer resin may be present in an amount of about 50 wt % to about 85 wt %, for example, about 60 wt % to about 80 wt %. Within this range, particularly, the plastic member can exhibit excellent stiffness and chemical resistance.

The base resin can include the rubber-modified aromatic vinyl graft copolymer resin in an amount of about 5 wt % to about 40 wt %, for example, about 5 wt % to about 20 wt %, based on the total weight (100wt %) of the base resin including the polycaebonate resin (A) and the rubber-modified aromatic vinyl graft copolymer resin (B) in the plastic member. In some embodiments, the base resin may include the rubber-modified aromatic vinyl graft copolymer resin in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40 wt %. Further, according to some embodiments of the present invention, the amount of the rubber-modified aromatic vinyl graft copolymer resin can be in a range from about any of the foregoing amounts to about any other of the foregoing amounts.

When the base resin includes the rubber-modified aromatic vinyl graft copolymer resin in an amount within this range, the plastic member can have an excellent balance of impact strength, heat resistance, and processability.

(C) Bondable Glass Fiber

The bondable glass fibers are glass fibers coated with a bondable organic material. The bondable glass fibers (C) exhibit strong bonding strength to the base resins (A) and (B), and thus can prevent the plastic member from whitening due to an ejector pin even when the plastic member is released at a high temperature of 30° C. or more.

For example, the bondable glass fibers may be coated with a bondable organic material such as but not limited to epoxy resin, urethane resin, silane resin, and the like, and mixtures thereof. In exemplary embodiments, the bondable glass fibers can be coated with an epoxy resin.

The glass fibers may have an entirely or partially coated surface. In one embodiment, coating may be performed by spray coating of about 0.01 parts by weight to about 1.0 part by weight of the bondable organic material based on about 100 parts by weight of the glass fibers. In some embodiments, the glass fibers may include a bondable organic material on part of or an entire surface thereof in an amount of about 0.01, 0.02, 0.03, 0.04, 0.05, 0.06, 0.07, 0.08, 0.09, 0.1, 0.2, 0.3, 0.4, 0.5, 0.6, 0.7, 0.8, 0.9, or 1.0 part by weight. Further, according to some embodiments of the present invention, the amount of the organic material can be in a range from about any of the foregoing amounts to about any other of the foregoing amounts.

The epoxy resin may be a typical epoxy resin for fiber coating, which can exhibit excellent properties in terms of fiber protection, strand integrity, wetting, and solubility. Examples of the epoxy resin may include without limitation epoxy (bisphenol A type), and the like, and combinations thereof.

The urethane resin may be a typical urethane resin for fiber coating, which can exhibit excellent strand integrity, fiber forming capability, and the like. Examples of the urethane resin may include without limitation polypropylene glycol (PPG) and isophorone diisocyanate (IPDI) polyurethane, and the like, and combinations thereof.

The silane resin may be a typical silane resin for fiber coating, which can exhibit excellent glass bonding properties. Examples of the silane resin may include without limitation 3-isocyanatopropyl triethoxysilane, and the like, and combinations thereof.

The bondable glass fibers may have an average length from about 2 mm to about 5 mm, and a diameter from about 10 μm to about 20 μm. Within this range, the bondable glass fibers can be easily introduced, exhibit excellent stiffness, and can be prevented from protruding from a surface of the plastic member.

The bondable glass fibers may have a circular or elliptical cross-section. In one embodiment, the bondable glass fibers may have a ratio (a/b) of (a) major diameter to (b) minor diameter from about 1.0 to about 1.2. Within this range, the bondable glass fibers can exhibit excellent dimensional stability.

The plastic member may include the bondable glass fibers in an amount of about 5 parts by weight to about 25 parts by weight, for example, about 10 parts by weight to about 20 parts by weight, based on about 100 parts by weight of the base resin including polycarbonate resin (A) and rubber-modified aromatic vinyl graft copolymer resin (B) in the plastic member. In some embodiments, the plastic member may include the bondable glass fibers in an amount of about 5, 6, 7, 8, 9, 10, 11, 12, 13, 14, 15, 16, 17, 18, 19, 20, 21, 22, 23, 24, or 25 parts by weight. Further, according to some embodiments of the present invention, the amount of the bondable glass fibers can be in a range from about any of the foregoing amounts to about any other of the foregoing amounts.

When the plastic member includes the bondable glass fibers in an amount within the above range, the plastic member can exhibit excellent stiffness, external appearance and the like, and prevent whitening upon release.

The plastic member may further include a flame retardant for improvement of flame retardancy.

Examples of the flame retardant may include without limitation phosphorus flame retardants, halogen flame retardants, and the like, and mixtures thereof. For example, the flame retardant may be a phosphorus flame retardant. The phosphorus flame retardant refers to a typical flame retardant containing phosphorus. Examples of the phosphorus flame retardant may include without limitation red phosphorus, phosphates, phosphonates, phosphinates, phosphine oxides, phosphazenes, metallic salts thereof, and the like, and mixtures thereof.

The plastic member may include the flame retardant in an amount of about 5 parts by weight to about 30 parts by weight, for example, about 12 parts by weight to about 20 parts by weight, based on about 100 parts by weight of the base resin include the polycarbonate resin (A) and the rubber-modified aromatic vinyl graft copolymer resin (B) in the plastic member. In some embodiments, the plastic member may include the flame retardant in an amount of about 5, 6, 7, 8, 9, 10, 11, 12, 13, 14, 15, 16, 17, 18, 19, 20, 21, 22, 23, 24, 25, 26, 27, 28, 29, or 30 parts by weight. Further, according to some embodiments of the present invention, the amount of the flame retardant can be in a range from about any of the foregoing amounts to about any other of the foregoing amounts.

When the plastic member includes the flame retardant in an amount within this range, the plastic member can exhibit excellent flame retardancy with no or minimal deterioration of other properties.

In addition, the plastic member may further include one or more typical additives such as but not limited to impact reinforcing agents, anti-dripping agents, antimicrobials, heat stabilizers, antioxidants, release agents, light stabilizers, inorganic additives, surfactants, plasticizers, lubricants, antistatic agents, colorants, and the like, and combinations thereof, as needed.

According to the invention, the plastic member may have a tensile strength from about 70 MPa to about 130 MPa, for example, from about 80 MPa to about 120 MPa at about 23° C., as measured on a tensile test specimen under conditions of about 50 mm/min in accordance with ASTM D638. If the plastic member has a tensile strength of less than about 70 MPa, the plastic member can suffer from whitening due to an ejector pin upon release, and if the plastic member has a tensile strength of greater than about 130 MPa, the plastic member can suffer from failure upon release.

The plastic member may have a gloss of about 95 or more, for example, from about 95 to about 100 as measured in accordance with ASTM D 2457, and a surface roughness (Ra) of about 20 nm or less, for example, from about 20 nm to about 5 nm as measured in accordance with ASTM D 4417-B. In addition, since the plastic member can exhibit excellent dimensional stability, the plastic member may have a coefficient of linear thermal expansion (a) of about 40 μm/(m° C.) or less, for example, from about 40 μm/(m° C.) to about 30 μm/(m° C.) as measured in accordance with ASTM D-696, and a shrinkage of about 0.003 cm/cm or less, for example, from about 0.003 cm/cm to about 0.002 cm/cm as measured in accordance with ASTM C356.

The present invention also relates to a method of fabricating a television housing. According to the invention, the method of fabricating a television housing includes: preparing a plastic member by injection of (A) a polycarbonate resin, (B) a rubber-modified aromatic vinyl graft copolymer resin and (C) bondable glass fibers into a mold in a steam molding process, followed by releasing the plastic member at about 30° C. to about 90° C.; and coupling the plastic member to a stainless steel (SUS) frame.

In one embodiment, the steam molding process may be rapid heat cycle molding (RHCM). RHCM can be performed by heating a mold to a temperature of a glass transition temperature (Tg) or more of a resin using steam, and then injecting a resin composition into the heated mold, followed by releasing a plastic member formed by curing the injected resin composition at about 30° C. to about 90° C. Although cycle time of overall processes may be reduced by decreasing cooling time of the plastic member in preparation of a television housing, the plastic member can suffer from whitening due to an ejector pin upon release. However, when the plastic member according to the invention is used, the plastic member can prevent whitening due to an ejector pin.

A preparation method of a television housing including RHCM may be easily performed by those skilled in the art.

Hereinafter, the present invention will be described in more detail with reference to the following examples. However, it should be understood that these examples are provided for illustration only and are not to be in any way construed as limiting the present invention.

### EXAMPLES

Details of components used in Examples and Comparative Examples are as follows:

(A) Polycarbonate Resin
PC-1: Polycarbonate resin (Cheil Industries Inc.) having a melt index MI (300° C., 1.2 kg) of 20 g/10 min as measured in accordance with ISO 1133
PC-2: Polycarbonate resin (Cheil Industries Inc.) having a melt index (300° C., 1.2 kg) of 62 g/10 min as measured in accordance with ISO 1133

(B) Rubber-Modified Aromatic Vinyl Graft Copolymer Resin

(B1) g-ABS: g-ABS (CHPC, Cheil Industries Inc.), in which an acrylonitrile-styrene copolymer having a weight ratio (SM/AN) of styrene monomer/acrylonitrile of 71/29 is grafted to a polybutadiene rubber (PBR) having a 45 wt % Z-average of 310 nm

(B2) SAN: SAN resin (styrene acrylonitrile copolymer) having MI of 5 g/10 min (200° C., 5 kg) and a weight average molecular weight (Mw) of 150,000 g/mol and including 24 wt % of acrylonitrile

### Examples 1 to 3 and Comparative Example 1

A polycarbonate resin, a rubber-modified aromatic vinyl graft copolymer resin and bondable glass fibers are mixed in a composition as listed in Table 1, followed by adding 15.5 parts by weight of BDP (Bisphenol A bis(diphenyl phosphate), Daihachi Co., Ltd.) to the mixture as a flame retardant based on 100 parts by weight of the mixture, thereby preparing a resin composition. Next, the resin composition is subjected to extrusion at 250° C. using a twin-screw extruder having a diameter of 45 mm and 36 L/D, thereby preparing pellets. The prepared pellets are injected into a mold heated in the same manner as in RHCM, followed by cooling to 70° C. and releasing a molded product using an ejector pin, thereby preparing a plastic member.

TABLE 1

| | | | | Comparative |
|---|---|---|---|---|
| | Example 1 | Example 2 | Example 3 | Example 1 |
| PC-1 (wt %) | 30 | 30 | 30 | 30 |
| PC-2 (wt %) | 40 | 40 | 40 | 40 |
| g-ABS (wt %) | 8 | 8 | 8 | 8 |
| SAN (wt %) | 5 | 5 | 5 | 5 |
| Glass fiber (wt %) | 17 | 17 | 17 | 17 |
| Cross-sectional shape of glass | Round | Round | Round | Round |
| fiber | | | | |
| Size of glass fiber | 3 mm/13 μm | 3 mm/10 μm | 3 mm/13 μm | 3 mm/13 μm |
| (Length/Diameter) | | | | |
| Coating material for glass | Epoxy | Urethane | Silane | — |
| fiber | | | | |
| GF Maker | KCC | Nittobo | Owenscorning | Nittobo |
| Grade Name | CS321-EC10-3 | ECS 03T-187H | 183F | CSF 3PE-936S |

### Experimental Example

The pellets prepared by extrusion in Examples 1 to 3 and Comparative Example 1 are dried at 80° C. for 4 hours, followed by molding at 250° C. to 280° C. and at a mold temperature of 60° C. to 150° C. using a 6-oz injection machine, thereby preparing specimens. Properties of the specimens are evaluated by the following methods. Results are shown in Table 2.

Property Evaluation

(1) Tensile strength (unit: kgf/cm²): Tensile strength is measured at 23° C. in accordance with ASTM D638 (kgf/cm²×0.098=MPa).

(2) Tensile elongation (unit: %): Tensile elongation is measured in accordance with ASTM D638.

(3) Izod impact strength (unit: kgf·cm/cm): Izod impact strength is measured on a notched Izod specimen at room temperature in accordance with ASTM D256 (⅛″, notched).

(4) Flame retardancy: Flame retardancy is measured on a 1.5 mm thick specimen according to the UL-94 VB test method.

(5) Ejector pin whitening: The prepared plastic member is released by 10 ejector pins at 70° C. The number of whitening marks (ejector pin whitening marks) caused by the 10 ejector pins upon release is observed by the naked eye, and the plastic member is evaluated according to the following grades:

1: number of whitening makrs from 10 to 8; 2: number of whitening marks from 7 to 5; 3: number of whitening marks from 4 to 2; and 4: number of whitening marks from 1 to 0.

TABLE 2

| | | | | Comparative |
|---|---|---|---|---|
| | Example 1 | Example 2 | Example 3 | Example 1 |
| Tensile strength (TS) | 1195 | 958 | 1179 | 661 |
| Tensile elongation | 5.1 | 5.4 | 5.2 | 5.0 |
| (TE) | | | | |
| Izod impact strength | 5.6 | 5.1 | 5.7 | 5.4 |
| Flame retardancy | V-1 | V-1 | V-1 | V-1 |
| Ejector pin whitening | 4 | 4 | 4 | 1 |

From the results of Table 2, it can be seen that the plastic members (Examples 1 to 3) according to the invention using bondable glass fibers exhibit extremely excellent tensile strength without deterioration of flame retardancy, stiffness and the like, and did not suffer from substantial whitening due to the ejector pins even at 70° C.

Conversely, it can be seen that the plastic member of Comparative Example 1 suffers from whitening due to the ejector pins upon release at high temperature, and deteriorated tensile strength.

That is, it can be seen that the plastic member according to the invention can prevent whitening due to an ejector pin even upon release at high temperature, and thus can exhibit outstanding external appearance while reducing process time for preparation of a television housing.

Many modifications and other embodiments of the invention will come to mind to one skilled in the art to which this invention pertains having the benefit of the teachings presented in the foregoing description. Therefore, it is to be understood that the invention is not to be limited to the specific embodiments disclosed and that modifications and other embodiments are intended to be included within the scope of the appended claims.

Although specific terms are employed herein, they are used in a generic and descriptive sense only and not for purposes of limitation, the scope of the invention being defined in the claims.

What is claimed is:

1. A television housing having a structure comprising:
a stainless steel (SUS) frame; and
a plastic member adjoining at least one surface of the stainless steel frame,
wherein the plastic member comprises a base resin comprising about 60 wt % to about 95 wt % of (A) a polycarbonate resin; and about 5 wt % to about 40 wt % of (B) a rubber-modified aromatic vinyl graft copolymer resin; and about 5 parts by weight to about 25 parts by weight of (C) bondable glass fibers based on about 100 parts by weight of the base resin including the (A) polycarbonate resin and the (B) rubber-modified aromatic vinyl graft copolymer resin,
wherein the plastic member has a tensile strength from about 70 MPa to about 130 MPa at about 23° C.

2. The television housing according to claim 1, wherein the plastic member is molded by a steam molding process.

3. The television housing according to claim 1, wherein the steam molding process is rapid heat cycle molding (RHCM).

4. The television housing according to claim 1, wherein the bondable glass fibers are coated with a resin comprising epoxy resin, urethane resin, silane resin or a combination thereof.

5. The television housing according to claim 1, wherein the plastic member further comprises a phosphorus flame retardant, a halogen flame retardant, or a combination thereof.

6. The television housing according to claim 1, wherein the plastic member further comprises an additive selected from the group consisting of impact reinforcing agents, anti-dripping agents, antimicrobials, heat stabilizers, antioxidants, release agents, light stabilizers, inorganic additives, surfactants, plasticizers, lubricants, antistatic agents, colorants and combinations thereof.

7. A method of fabricating a television housing, comprising:
preparing a plastic member by injection of (A) a polycarbonate resin, (B) a rubber-modified vinyl graft copolymer resin and (C) bondable glass fibers into a mold in a steam molding process, followed by releasing the plastic member at about 30° C. to about 90° C.; and
coupling the plastic member to a stainless steel (SUS) frame.

8. The method according to claim 7, wherein the plastic member has a tensile strength from about 70 MPa to about 130 MPa at about 23° C.

9. The method according to claim 7, wherein the steam molding process is rapid heat cycle molding (RHCM).
